(19) United States
(12) Patent Application Publication
(10) Pub. No.: US 2025/0221221 A1
(43) Pub. Date: Jul. 3, 2025

(54) DISPLAY DEVICE

(71) Applicant: LG Display Co., Ltd., Seoul (KR)

(72) Inventor: Chang Hwa JUN, Paju-si (KR)

(21) Appl. No.: 18/958,658

(22) Filed: Nov. 25, 2024

(30) Foreign Application Priority Data
Dec. 29, 2023 (KR) 10-2023-0196668

(51) Int. Cl. H10K 59/35

(52) U.S. Cl. CPC H10K 59/353; H10K 59/352

(57) ABSTRACT

An embodiment discloses a display device including a substrate, a plurality of sub-pixels disposed on the substrate in a first direction and a second direction intersecting each other, and a first trench and a second trench disposed between the plurality of sub-pixels and extending in the second direction, wherein a first spacing region where the first trench and the second trench are spaced apart from each other at a first interval and a second spacing region where the first trench and the second trench are spaced apart from each other at a second interval larger than the first interval are disposed, and each of the plurality of sub-pixels is disposed in the second spacing region.

### CROSS-REFERENCE TO RELATED APPLICATION

This application claims priority to and the benefit of Korean Patent Application No. 10-2023-0196668, filed on Dec. 29, 2023, the disclosure of which is incorporated herein by reference in its entirety.

### BACKGROUND

### Technical Field

Embodiments relate to a display device.

### Description of the Related Art

Personal immersive devices are being developed in various types such as a head mounted display (HMD), a face mounted display (FMD), an eye glasses-type display (EGD), and the like. The personal immersive devices are classified as virtual reality (VR) devices or augmented reality (AR) devices.

In the personal immersive device, sub-pixels should be formed at a dense interval for high resolution, and in this case, there is a problem of a leakage current occurring in boundary regions between adjacent sub-pixels.

### BRIEF SUMMARY

One embodiment is directed to providing a display device capable of blocking a leakage current occurring between sub-pixels.

The technical problems to be solved by the embodiment are not limited to the above-mentioned technical problems, and other technical problems which are not mentioned herein may be clearly understood by those skilled in the art from the following description.

A display device according to one aspect of the present disclosure includes a substrate, a plurality of sub-pixels disposed on the substrate in a first direction and a second direction intersecting each other, and a first trench and a second trench disposed between the plurality of sub-pixels and extending in the second direction, wherein a first spacing region where the first trench and the second trench are spaced apart from each other at a first interval and a second spacing region where the first trench and the second trench are spaced apart from each other at a second interval larger than the first interval are disposed, and each of the plurality of sub-pixels is disposed in the second spacing region.

The plurality of sub-pixels may have sub-pixels of different colors disposed in the first direction and a diagonal direction intersecting the first direction and the second direction.

The plurality of sub-pixels may be disposed in a zigzag shape in the second direction.

The plurality of sub-pixels may include a first sub-pixel, a second sub-pixel, and a third sub-pixel with different colors, and the first sub-pixel is surrounded by the second sub-pixel and the third sub-pixel, and centers of the first sub-pixel, the second sub-pixel, and the third sub-pixel are disposed in a triangular shape.

Each of the plurality of sub-pixels may have a polygonal shape, an elliptical shape or a circular shape on a plane.

The plurality of sub-pixels may include a plurality of sub-pixels disposed on a first pixel line, and a plurality of sub-pixels disposed on a second pixel line spaced apart from the first pixel line, and the plurality of sub-pixels disposed on the first pixel line may be disposed to be misaligned from the plurality of sub-pixels disposed on the second pixel line in the second direction.

The first trench and the second trench may be disposed to be spaced apart from each other at the first interval between the plurality of sub-pixels disposed on the first pixel line, and may be bent in directions far away from each other and disposed to be spaced apart from each other at the second interval between the plurality of sub-pixels disposed on the second pixel line.

The plurality of sub-pixels may include a plurality of first electrodes disposed in the plurality of sub-pixels on the substrate, a light-emitting layer disposed on the plurality of first electrodes, and a second electrode disposed on the light-emitting layer, the plurality of sub-pixels may be partitioned by the first trench and the second trench, and portions of the light-emitting layer may be disconnected by the first trench and the second trench.

The light-emitting layer may include a first stack, a charge generation layer disposed on the first stack, and a second stack disposed on the charge generation layer, and the first stack and the charge generation layer may be disconnected by the first trench and the second trench, and at least a portion of the second stack is connected continuously.

The first trench and the second trench may include first portions extending in a direction parallel to the second direction, second portions extending in a direction intersecting the second direction, and bent regions where the first portions and the second portions are connected, and curvature may be formed in each of the bent regions.

The second direction may be perpendicular to the first direction.

The display device may comprise a first pixel group disposed in a first display region and a second pixel group disposed in a second display region surrounding the first display region, a size of the plurality of sub-pixels disposed in the second display region is larger than a size of the plurality of sub-pixels disposed in the first display region, wherein a plurality of third trenches extending in the second direction are disposed between the sub-pixels of the first pixel group, and the first trench and the second trench are disposed between the sub-pixels of the second pixel group, and wherein the display device may further comprise a third spacing region where the plurality of third trenches are spaced apart from each other at a third interval, and the third spacing region is wider than the first spacing region and narrower than the second spacing region.

At a boundary between the first display region and the display region, the sub-pixels of the first display region and the sub-pixels of the second display region may be disposed to face each other with the same color.

The third trenches may be connected to the first trench and the second trench.

The third trenches may be not connected to the first trench and the second trench.

A display device according to another aspect of the present disclosure includes: a

substrate; a plurality of sub-pixels disposed on the substrate in a first direction and a second direction perpendicular to the first direction, and trenches disposed between the plurality of sub-pixels, wherein the number of trenches disposed between the sub-pixels disposed in the first direction is greater than or equal to the number of trenches disposed between the sub-pixels disposed in a diagonal direction.

The plurality of sub-pixels may have sub-pixels of different colors disposed in the first direction and in the diagonal direction, and the diagonal direction may be a direction intersecting the first direction and the second direction.

The trenches disposed between the sub-pixels disposed in the first direction may be connected to the trenches disposed between the sub-pixels disposed in the diagonal direction.

Two grooves may be disposed between the sub-pixels disposed in the first direction, and one groove may be disposed between the sub-pixels disposed in the diagonal direction.

Two grooves may be disposed between the sub-pixels disposed in the first direction, and two grooves may be disposed between the sub-pixels disposed in the diagonal direction.

One groove may be disposed between the sub-pixels disposed in the first direction, and one groove may be disposed between the sub-pixels disposed in the diagonal direction.

### BRIEF DESCRIPTION OF THE SEVERAL VIEWS OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is a view illustrating sub-pixels of a display device according to one embodiment of the present disclosure;

FIG. 2 is a cross-sectional view taken along line I-I′ in FIG. 1;

FIG. 3 is a cross-sectional view taken along line II-II′ in FIG. 1;

FIG. 4 is a cross-sectional view of a light-emitting layer;

FIG. 5 is an enlarged view of portion A in FIG. 2;

FIG. 6 is a view illustrating a state in which trenches disposed between sub-pixels are connected to each other;

FIG. 7 is a view illustrating a point where the trenches in FIG. 6 are connected to each other;

FIG. 8 is a cross-sectional view taken along line III-III′ in FIG. 7;

FIG. 9 is a view illustrating a first modified example of the trenches according to one embodiment of the present disclosure;

FIG. 10 is a view illustrating a second modified example of the trenches according to one embodiment of the present disclosure;

FIG. 11 is a view illustrating a third modified example of the trenches according to one embodiment of the present disclosure;

FIG. 12 is a view illustrating sub-pixels of a display device according to another embodiment of the present disclosure;

FIG. 13 is a view illustrating sub-pixels of a display device according to still another embodiment of the present disclosure;

FIG. 14 is an enlarged view of portion B in FIG. 13;

FIG. 15 is a modified example of FIG. 14;

FIG. 16 is a view illustrating an example of a personal immersive device of a head mounted display (HMD) type; and

FIG. 17 is a block diagram illustrating an example of a display device applicable to the personal immersive device.

### DETAILED DESCRIPTION

Advantages and features of the present disclosure, and methods of achieving them will become apparent with reference to the following embodiments, which are described in detail, in conjunction with the accompanying drawings. However, the present disclosure is not limited to the embodiments to be described below and may be implemented in various different forms, the embodiments are only provided to completely disclose the present specification and completely convey the scope of the present disclosure to those skilled in the art, and the claims are not limited by the present disclosure.

Since the shapes, sizes, proportions, angles, numbers, and the like disclosed in the drawings for describing the embodiments of the present disclosure are only exemplary, the present disclosure is not limited to the items shown in the drawings. The same reference numerals refer to the same components throughout the specification. Further, in describing present disclosure, when it is determined that a detailed description of related known technology may unnecessarily obscure the gist of the present disclosure, the detailed description thereof will be omitted.

When “providing,” “including,” “having,” “consisting of,” and the like mentioned in the present specification are used, other parts may be added unless “only” is used. A case where a component is expressed in a singular form includes a plural form unless explicitly stated otherwise.

In interpreting the components, it should be understood that an error range is included even when there is no separate explicit description.

When positional relationships and interconnection relationships between two components such as “on,” “at an upper portion,” “at a lower portion,” “next to,” “connect or couple,” “crossing or intersecting,” and the like are described, one or more other components may be interposed between the two components unless “immediately” or “directly” is mentioned.

A case where temporal relationships are described as “after,” “in succession to,” “and then,” “before,” and the like may not be continuous on a time axis unless “immediately” or “directly” is used.

In the description of the embodiments, although first, second, and the like are used to describe various components, these components are not limited by these terms. These terms are only used to distinguish one component from another component. Accordingly, a first component to be mentioned below may also be a second component within the technical spirit of the present specification.

The same reference numerals refer to the same components throughout the specification.

Features of various embodiments may be partially or entirely coupled to or combined with each other, and technically, various types of interconnections and driving are possible, and the embodiments may be implemented independently of each other or may be implemented together in a related relationship.

Hereinafter, various embodiments of the present disclosure will be described in detail with reference to the accompanying drawings.

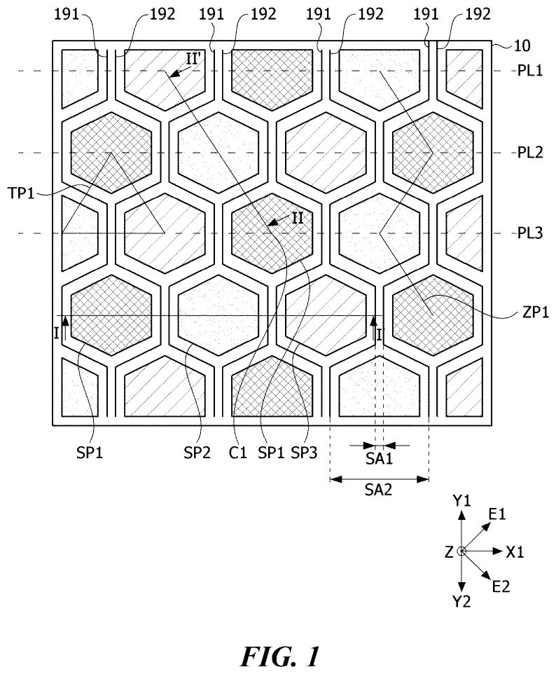

FIG. 1 is a view illustrating sub-pixels of a display device according to one embodiment of the present disclosure.

Referring to FIG. 1, the display device according to the embodiment includes a plurality of sub-pixels SP1, SP2, and SP3 disposed on a substrate 110 in a first direction (an X-axis direction) and a second direction (a Y-axis direction) intersecting to the first direction, and first trenches 191 and second trenches 192 disposed between the plurality of sub-pixels SP1, SP2, and SP3 and extending in the second direction (the Y-axis direction). In the embodiment, an example in which the number of trenches is two is described, but the number of trenches is not limited thereto. Wherein, the second direction may be perpendicular to the first direction, but not limited thereto.

The plurality of sub-pixels SP1, SP2, and SP3 may be disposed on a plurality of pixel lines PL1, PL2, and PL3 disposed in the first direction (the X-axis direction). The plurality of pixel lines may be disposed to be spaced apart from each other in the second direction (the Y-axis direction).

For example, a first sub-pixel SP1, a second sub-pixel SP2, and a third sub-pixel SP3 may be sequentially disposed on a first pixel line PL1 in the first direction (the X-axis direction). Further, the first sub-pixel SP1, the second sub-pixel SP2, and the third sub-pixel SP3 may be sequentially disposed on a second pixel line PL2 in the first direction (the X-axis direction).

The first sub-pixel SP1, the second sub-pixel SP2, and the third sub-pixel SP3 may be sub-pixels of different colors. For example, the first sub-pixel SP1 may be a red sub-pixel, the second sub-pixel SP2 may be a green sub-pixel, and the third sub-pixel SP3 may be a blue sub-pixel. However, the present disclosure is not necessarily limited thereto, and a color of each sub-pixel may be changed in various ways.

The plurality of sub-pixels SP1, SP2, and SP3 disposed on the first pixel line PL1 and the plurality of sub-pixels SP1, SP2, and SP3 disposed on the second pixel line PL2 may be disposed to be misaligned from each other. Accordingly, the plurality of sub-pixels SP1, SP2, and SP3 may be disposed in a zigzag shape in the second direction (the Y-axis direction). A zigzag shape ZP1 may be defined as a shape disposed so that virtual lines which connects centers of the sub-pixels disposed in the second direction (the Y-axis direction) are not parallel to the second direction (the Y-axis direction) and repeatedly become close to and away from a vertical line parallel to the second direction (the Y-axis direction). Here, the second direction (the Y-axis direction) may be defined as a concept including a 2-1 direction (a Y1-axis direction) and a 2-2 direction (a Y2-axis direction).

The plurality of sub-pixels SP1, SP2, and SP3 may have sub-pixels of different colors disposed in the first direction (the X-axis direction) and diagonal directions (E1 and E2 directions). The diagonal directions (the E1 and E2 directions) may be directions intersecting the first direction (the X-axis direction) and the second direction (the Y-axis direction) and in which the plurality of sub-pixels SP1, SP2, and SP3 are sequentially disposed. The plurality of sub-pixels SP1, SP2, and SP3 may have sub-pixels of different colors sequentially disposed in the first direction (the X-axis direction), and sub-pixels of different colors sequentially disposed in the diagonal directions (the E1 and E2 directions).

For example, the second sub-pixel SP2 and the third sub-pixel SP3 may be disposed at both sides in the first direction (the X-axis direction), and the second sub-pixel SP2 and the third sub-pixel SP3 may also be disposed in the diagonal directions (the E1 and E2 directions) based on the first sub-pixel SP1 disposed at a center C1. That is, the first sub-pixel SP1 may be surrounded by the second sub-pixel SP2 and the third sub-pixel SP3. This structure may be defined as a delta pixel structure. Alternatively, a structure in which the sub-pixels SP1, SP2, and SP3 constituting a pixel are disposed in a triangular shape TP1 may be defined as the delta pixel structure. However, the present disclosure is not necessarily limited thereto, and the first to third sub-pixels SP1, SP2, and SP3 disposed in the first direction (the X-axis direction) may constitute one pixel.

A personal immersive device may use a delta pixel structure to reduce fatigue of user's eyes. The delta pixel structure may reduce fatigue of eyes by increasing color dispersion because the sub-pixels of different colors are disposed in up, down, left and right directions, and diagonal directions.

Although an example in which each of the plurality of sub-pixels SP1, SP2, and SP3 has a hexagonal shape is described, the shape of the sub-pixel is not necessarily limited thereto, and the sub-pixels may be composed of various polygonal shapes such as a triangular shape, a quadrangular shape, an octagonal shape, and the like. Further, the plurality of sub-pixels SP1, SP2, and SP3 may have a circular shape or an elliptical shape.

Although an example in which sizes and shapes of the plurality of sub-pixels SP1, SP2, and SP3 are all the same is described, the shapes and sizes of the plurality of sub-pixels SP1, SP2, and SP3 may be different from each other. For example, at least one of the first sub-pixel SP1, the second sub-pixel SP2, and the third sub-pixel SP3 may be manufactured with a different size. At least one of the first sub-pixel SP1, the second sub-pixel SP2, and the third sub-pixel SP3 may be manufactured with a different shape.

The first trench 191 and the second trench 192 may be disposed between the plurality of sub-pixels SP1, SP2, and SP3. The first trench 191 and the second trench 192 may extend in the second direction (the Y-axis direction) while being spaced apart from each other. In this case, the first trench 191 and the second trench 192 may be spaced apart from each other at a predetermined interval while extending in the second direction (the Y-axis direction) and thus may not meet each other.

A first spacing region SA1 having a first interval and a second spacing region SA2 having a second interval larger than the first interval may be repeatedly formed on the substrate 110 by the first trench 191 and the second trench 192. A plurality of first spacing regions SA1 and a plurality of second spacing regions SA2 may be alternately disposed in the second direction (the Y-axis direction). The plurality of sub-pixels SP1, SP2, and SP3 may be respectively disposed in the plurality of second spacing regions SA2. Accordingly, since a light-emitting layer 140 of each sub-pixel is separated from a light-emitting layer 140 of the neighboring sub-pixel, a leakage current may be blocked.

The first trench 191 and the second trench 192 may form the first spacing region SA1 having the first interval on the first pixel line PL1, and may be bent in directions away from each other along side surfaces of the sub-pixels to form the second spacing region SA2 while extending to the second pixel line PL2. Thereafter, the first trench 191 and the second trench 192 may be bent in directions approaching each other to be disposed between the neighboring sub-pixels when extending to a third pixel line PL3 which is a next line.

Alternatively, on the other hand, the first trench 191 and the second trench 192 may be bent in the directions approaching each other along side surfaces of the sub-pixels while extending from the first pixel line PL1 to the second pixel line PL2. Thereafter, the first trench 191 and the second trench 192 may be bent in directions away from other along side surfaces of the sub-pixels when extending to the third pixel line PL3 which is the next line.

Both the first trench 191 and the second trench 192 are disposed on a line of the plurality of sub-pixels SP1, SP2, and SP3 disposed in the first direction (the X-axis direction), but only one of the first trench 191 and the second trench 192 may be disposed on a line of the plurality of sub-pixels SP1, SP2, and SP3 disposed in the diagonal directions (the E1 and E2 directions).

That is, the number of trenches disposed between the plurality of sub-pixels SP1, SP2, and SP3 disposed in the first direction (the X-axis direction) may be greater than the number of trenches disposed between the plurality of sub-pixels SP1, SP2, and SP3 disposed in the diagonal directions (the E1 and E2 directions). In this case, the trenches disposed in the first direction may be connected to the trenches disposed in the diagonal directions.

According to the embodiment, the plurality of first trenches 191 and the second trenches 192 may extend in the second direction (the Y-axis direction) and alternately form the plurality of first spacing regions SAI and second spacing regions SA2, and the plurality of sub-pixels SP1, SP2, and SP3 may be disposed in each second spacing region SA2. Accordingly, the plurality of sub-pixels SP1, SP2, and SP3 may be separated from the light-emitting layers of adjacent sub-pixels in the first direction (the X-axis direction) and the diagonal directions (the E1 and E2 directions) to prevent a leakage current.

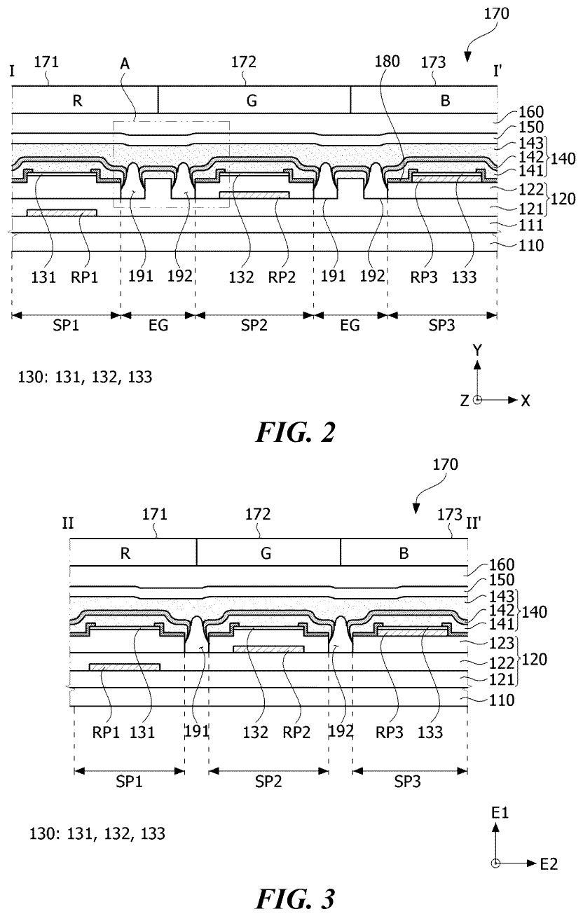

FIG. 2 is a cross-sectional view taken along line I-I′ in FIG. 1, and FIG. 3 is a cross-sectional view taken along line II-II′ in FIG. 1.

Referring to FIGS. 2 and 3, the display device may include a plurality of first electrodes 130 respectively disposed in the first sub-pixel to the third sub-pixel SP1, SP2, and SP3, the light-emitting layer 140 disposed on the plurality of first electrodes 130, and a second electrode 150 disposed on the light-emitting layer 140.

The substrate 110 may be composed of glass or plastic. However, the substrate 110 is not necessarily limited thereto, and may be composed of a semiconductor material such as a silicon wafer.

The first sub-pixel SP1, the second sub-pixel SP2, and the third sub-pixel SP3 may be disposed on the substrate 110. The first sub-pixel SP1 may emit red light, the second sub-pixel SP2 may emit green light, and the third sub-pixel SP3 may emit blue light. However, the light emitted by each sub-pixel may be changed in various ways.

The display device according to the embodiment may have a top emission structure in which light is emitted upward. Accordingly, an opaque material as well as a transparent material may be used as a material of the substrate 110.

Circuit elements including various signal lines, thin film transistors, capacitors, and the like may be provided on a circuit element layer 111 for each of the plurality of sub-pixels SP1, SP2, and SP3. The signal lines may include gate lines, data lines, power lines, and reference lines, and thin film transistors may include switching thin film transistors, driving thin film transistors, and sensing thin film transistors.

Reflective electrodes RP1, RP2, and RP3 may be patterned for the plurality of sub-pixels SP1, SP2, and SP3 on the circuit element layer 111, respectively. Specifically, a first reflective electrode RP1 may be patterned on the first sub-pixel SP1, a second reflective electrode RP2 may be patterned on the second sub-pixel SP2, and a third reflective electrode RP3 may be patterned on the third sub-pixel SP3.

The reflective electrodes RP1, RP2, and RP3 may serve to realize micro cavity properties in the plurality of sub-pixels SP1, SP2, and SP3, respectively. Accordingly, a distance from the first reflective electrode RP1 to the second electrode 150 may be longer than a distance from the second reflective electrode RP2 to the second electrode 150, and the distance from the first reflective electrode RP1 to the second electrode 150 may be longer than a distance from the third reflective electrode RP3 to the second electrode 150. The first reflective electrode RP1 may be formed on an upper surface of the circuit element layer 111, the second reflective electrode RP2 may be formed on an upper surface of a first insulating layer 121, and the third reflective electrode RP3 may be formed on an upper surface of a second insulating layer 122.

The first electrode 130 may comprise a first electrode 131 disposed in the first sub-pixel SP1, a first electrode 132 disposed in the second sub-pixel SP2 and a first electrode 133 disposed in the third sub-pixel SP3.

The first reflective electrode RP1 may be electrically insulated from the first electrode 131 of the first sub-pixel SP1, but may be electrically connected to the first electrode 131 of the first sub-pixel SP1 through a contact hole (not shown) provided in an insulating layer 120.

The second reflective electrode RP2 may be electrically insulated from the first electrode 132 of the second sub-pixel SP2, but may be electrically connected to the first electrode 132 of the second sub-pixel SP2 through a contact hole (not shown) provided in the second insulating layer 122.

The third reflective electrode RP3 may be provided in contact with a lower surface of the first electrode 133 of the third sub-pixel SP3, but in some cases, an insulating layer may be disposed between the third reflective electrode RP3 and the first electrode 133 of the third sub-pixel SP3.

The insulating layers 120 may include the first insulating layer 121 provided on the circuit element layer 111 and the second insulating layer 122 provided on the first insulating layer 121, but the number of insulating layers 120 is not necessarily limited thereto.

The trenches 191 and 192 may be formed in boundary regions EG between the plurality of sub-pixels SP1, SP2, and SP3. The trenches 191 and 192 may be formed on the second insulating layer 122, but are not necessarily limited thereto, and may be formed on the first insulating layer 121.

The first trench 191 and the second trench 192 may be formed in each of the boundary regions EG of the sub-pixels. Depths and widths of the first trench 191 and the second trench 192 may be the same. However, the present disclosure is not necessarily limited thereto, and the depths and/or the widths of the first trench 191 and the second trench 192 may be different.

Referring to FIG. 3, either the first trench 191 or the second trench 192 may be formed between the sub-pixels disposed in the diagonal directions (the E1 and E2 directions). According to the embodiment, two trenches may be disposed between the sub-pixels disposed in the first direction (the X-axis direction), but one trench may be disposed between the sub-pixels disposed in the diagonal directions (the E1 and E2 direction).

The light-emitting layer 140 may be formed on the plurality of sub-pixels SP1, SP2, and SP3 and the boundary regions EG. The light-emitting layer 140 may be formed on the first electrodes 130 and fences 180.

The light-emitting layer 140 may be provided to emit white light (W). To this end, the light-emitting layer 140 may include a plurality of stacks which emit light of different colors.

The second electrode 150 may be formed on the light-emitting layer 140. The second electrode 150 may function as a cathode of the display device. The second electrode 150 may include a transparent conductive material to transmit light emitted from the light-emitting layer 140 upward. The second electrode 150 may be composed of a translucent electrode, and accordingly, a micro cavity effect may be acquired for each of the plurality of sub-pixels SP1, SP2, and SP3. When the second electrode 150 is composed of a translucent electrode, light is repeatedly reflected and re-reflected between the second electrode 150 and the reflective electrode RF and the micro cavity effect may be acquired. Accordingly, the light efficiency may be improved.

An encapsulation layer 160 is formed on the second electrode 150 to prevent external moisture from penetrating into the light-emitting layer 140. This encapsulation layer 160 may be formed of an inorganic insulating material or may be formed in a structure in which inorganic insulating materials and organic insulating materials are alternately stacked, but is not necessarily limited thereto.

A color filter layer 170 may be formed on the encapsulation layer 160. The color filter layer 170 may include a red color filter 171 disposed on the first sub-pixel SP1, a green color filter 172 disposed on the second sub-pixel SP2, and a blue color filter 173 disposed on the third sub-pixel SP3. Although not shown in the drawings, black matrices are additionally formed between the color filter layers 170 to prevent light from leaking at boundaries between the plurality of sub-pixels SP1, SP2, and SP3.

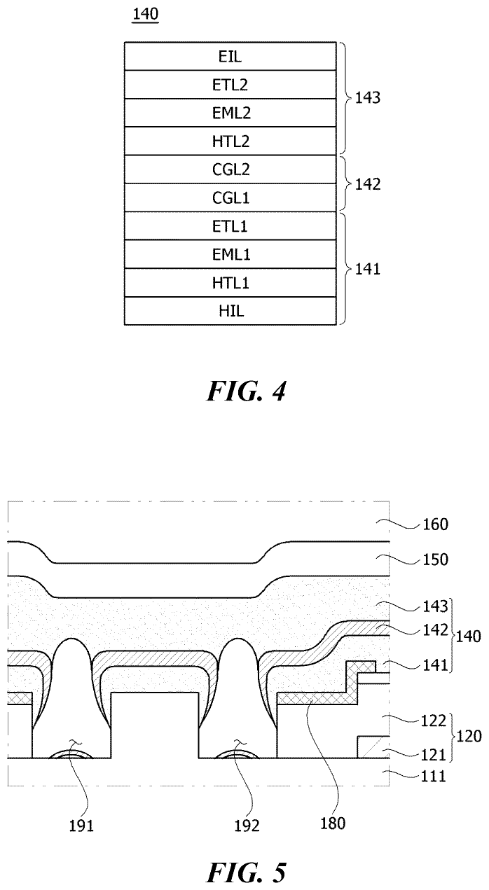

FIG. 4 is a cross-sectional view of the light-emitting layer. FIG. 5 is an enlarged view of portion A in FIG. 2.

Referring to FIGS. 4 and 5, the light-emitting layer 140 may include a first stack 141 which generates first light, a charge generation layer 142 disposed on the first stack 141, and a second stack 143 which is disposed on the charge generation layer 142 and generates second light.

The first stack 141 may include a hole injection layer HIL, a first hole transport layer HTL1 provided on the hole injection layer HIL, a first organic light-emitting layer EML1 provided on the first hole transport layer HTL1, and a first electron transport layer ETL1 provided on the first organic light-emitting layer EML1, but is not necessarily limited thereto. The first organic light-emitting layer EML1 may be composed of a yellow-green light-emitting layer or a blue light-emitting layer.

The charge generation layer 142 includes an n-type charge generation layer CGL1 provided on the first stack 141 and a p-type charge generation layer CGL2 provided on the n-type charge generation layer CGL1. The n-type charge generation layer CGL1 may provide electrons to the first stack 141, and the p-type charge generation layer CGL2 may provide holes to the second stack 143.

The second stack 143 may include a second hole transport layer HTL2 provided on the charge generation layer 142, a second organic light-emitting layer EML2 provided on the second hole transport layer HTL2, a second electron transport layer ETL2 provided on the second organic light-emitting layer EML2, and an electron injection layer EIL provided on the second electron transport layer ETL2, but is not necessarily limited thereto. The second organic light-emitting layer EML2 may be composed of a blue light-emitting layer 140 or a yellow green-light-emitting layer 140.

However, a stack structure of the light-emitting layer is not necessarily limited thereto, and a plurality of stacks may be further disposed. For example, a third stack (not shown) may be further disposed on the second stack 143. In this case, the first stack 141 may emit blue light, the second stack 143 may emit green light, and the third stack may emit red light. In this case, the charge generation layer may be disposed between the second stack and the third stack.

The charge generation layer 142 has relatively high electrical conductivity compared to other layers. Accordingly, when the charge generation layer 142 is connected between the plurality of sub-pixels SP1, SP2, and SP3 disposed adjacent to each other, it is possible that a leakage current occurs between the plurality of sub-pixels SP1, SP2, and SP3 disposed adjacent to each other through the charge generation layer 142.

Referring to FIG. 5, as the charge generation layer 142 is disconnected in the first trench 191 and the second trench 192, the leakage current may be prevented from occurring between the plurality of sub-pixels SP1, SP2, and SP3 disposed adjacent to each other. Further, at least a portion of the second stack 143 may be formed continuously on the charge generation layer 142 and may not be disconnected by the first trench 191 and the second trench 192. Accordingly, the second electrode 150 formed on the second stack 143 may not be inserted into the first trench 191 and the second trench 192. As a result, a problem of a short-circuit between the charge generation layer 142 and the second electrode 150 may be solved.

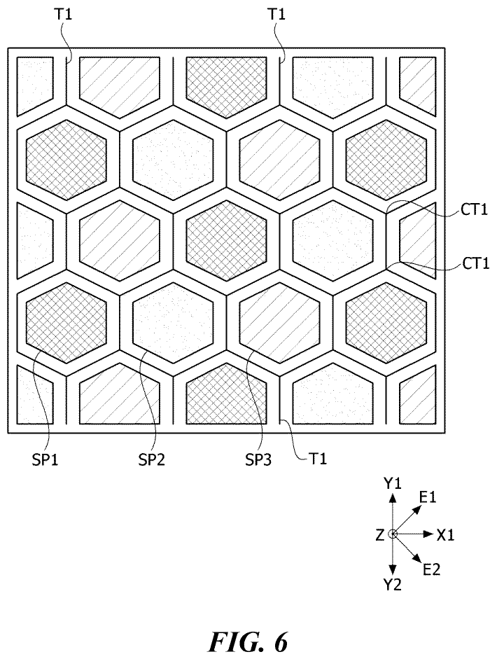

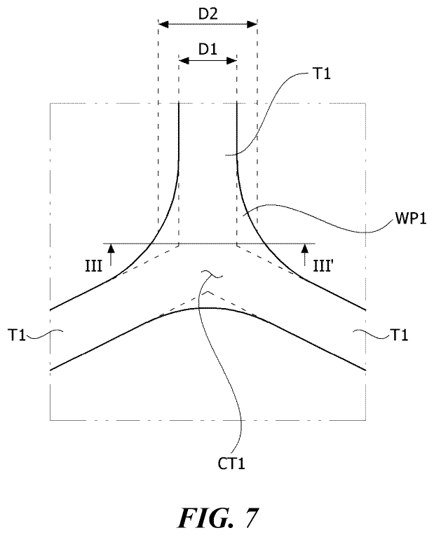

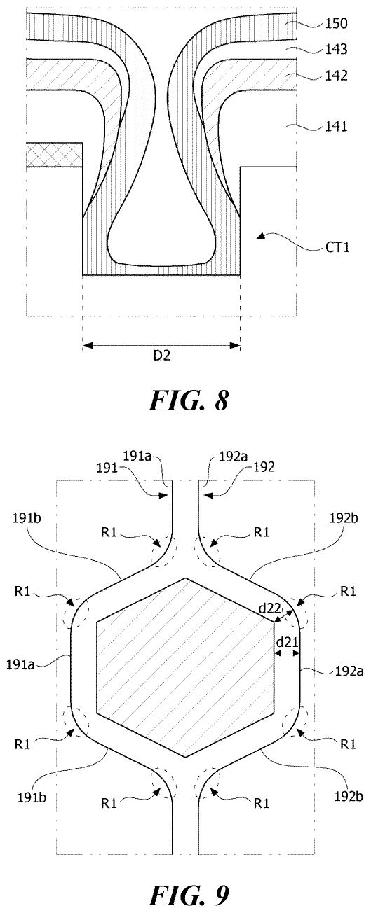

FIG. 6 is a view illustrating a state in which the trenches disposed between the sub-pixels are connected to each other. FIG. 7 is a view illustrating a point where the trenches in FIG. 6 are connected to each other. FIG. 8 is a cross-sectional view taken along line III-III′ in FIG. 7.

Referring to FIGS. 6 and 7, one trench T1 is formed between the plurality of sub-pixels SP1, SP2, and SP3, and trenches T1 formed between the plurality of sub-pixels SP1, SP2, and SP3 may all be connected. However, according to this configuration, a width may be relatively wide at a contact point portion CT1 at which trenches are connected.

A width D2 of the contact point portion CT1 at which the trenches having a certain line width D1 are connected may be wider by a certain portion WP1 compared to a contact point (a point where dotted line portions meet) at which the trenches are ideally connected.

Referring to FIG. 8, not only the first stack 141 and the charge generation layer 142 of the light-emitting layer 140 but also the second stack 143 may be entirely disconnected at the contact point portion of the trench T1. Accordingly, when the second electrode 150 is formed thereon, the second electrode 150 may extend to the inside of the trench T1. As a result, since the second electrode 150 comes into contact with the disconnected charge generation layer 142, current leakage may occur.

On the other hand, in the display device according to the embodiment, since two trenches disposed between the sub-pixels are not connected to each other and extend in the second direction (the Y-axis direction), there is no portion at which the trenches are connected, and a width may be constant. Accordingly, a problem in that the second electrode 150 is inserted into the trench and short-circuited with the charge generation layer may be prevented.

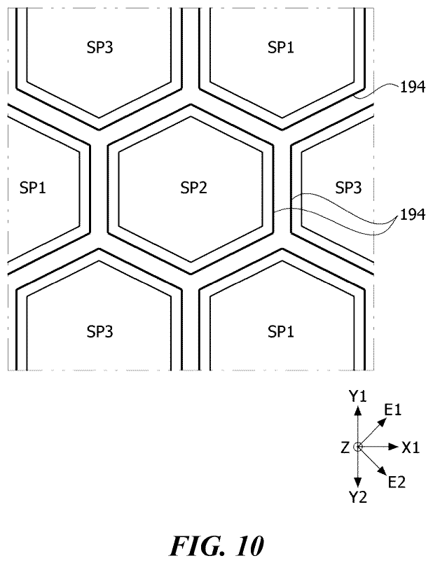

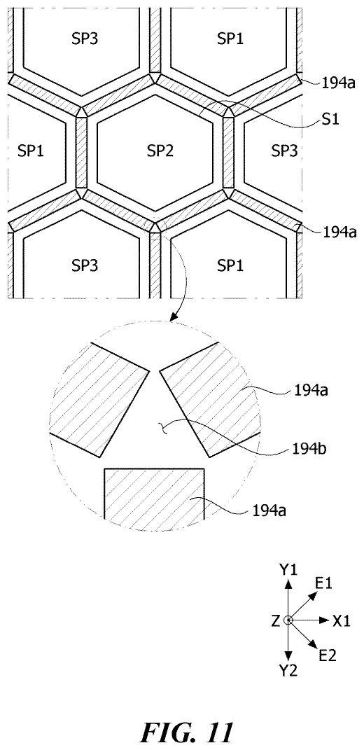

FIG. 9 is a view illustrating a first modified example of the trenches according to one embodiment of the present disclosure. FIG. 10 is a view illustrating a second modified example of the trenches according to one embodiment of the present disclosure. FIG. 11 is a view illustrating a third modified example of the trenches according to one embodiment of the present disclosure.

Referring to FIG. 9, the first trench 191 and the second trench 192 may include first portions 191a and 192a extending in a direction parallel to the second direction (the Y-axis direction), second portions 191b and 192b extending in a direction intersecting the second direction (the Y-axis direction), and bent regions R1 to which the first portions 191a and 192a and the second portions 191b and 192b are connected, and curvature may be formed in each of the bent regions R1.

The width of the trench may also increase at a portion which is bent during a patterning process. Accordingly, since a width of the bent region R1 of the trench is wider and the second electrode 150 is inserted, a short circuit with the charge generation layer may occur. According to the embodiment, as the curvatures of the bent regions R1 of the trenches are formed and the trenches are gently connected, a short circuit between the charge generation layer and the second electrode may be prevented even in bent region RI by maintaining a trench width d21 in a straight region and a trench width d22 in the bent region relatively constant.

Referring to FIG. 10, the trench may include a plurality of split trenches 194 respectively surrounding the sub-pixels. The plurality of split trenches 194 may be disposed to respectively surround the plurality of sub-pixels SP1, SP2, and SP3 and may be disposed to be spaced apart from each other.

According to this configuration, since the split trench 194 is disposed on each of the plurality of sub-pixels SP1, SP2, and SP3, the number of sub-pixels and the number of trenches may be the same. Further, two trenches may be disposed between the plurality of sub-pixels SP1, SP2, and SP3 in the first direction (the X-axis direction) and the diagonal directions (the E1 and E2 directions). That is, the number of trenches in the first direction (the X-axis direction) and the diagonal directions (the E1 and E2 directions) may be the same.

Referring to FIG. 11, the trench may include a plurality of sub-trenches 194a surrounding the plurality of sub-pixels SP1, SP2, and SP3. According to this configuration, since there are no contact points at which the sub-trenches 194a are connected, portions where a width of the trench is widened may be removed. A spacing portion 194b may be formed between the plurality of sub-trenches 194a.

The number of sub-trenches 194a may be variously changed depending on the shape of the sub-pixel. When the sub-pixel has a hexagonal shape, the number of sub-trenches 194a surrounding the sub-pixel may be six. When the sub-pixel has a triangular shape, the number of sub-trenches 194a surrounding the sub-pixel may be three.

According to this configuration, one trench may be disposed between the plurality of sub-pixels SP1, SP2, and SP3 in both the first direction (the X-axis direction) and the diagonal directions (the E1 and E2 directions). That is, the number of trenches in the first direction (the X-axis direction) and the diagonal directions (the E1 and E2 directions) may be the same.

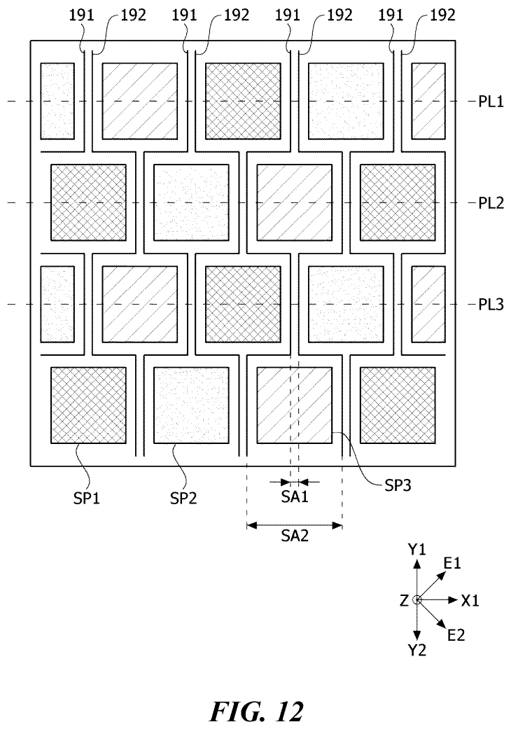

FIG. 12 is a view illustrating sub-pixels of a display device according to another embodiment of the present disclosure.

Referring to FIG. 12, the display device according to the embodiment includes a plurality of sub-pixels SP1, SP2, and SP3 disposed in a first direction (an X-axis direction) and a second direction (a Y-axis direction) perpendicular to the first direction (the X-axis direction) on a substrate 110, and first trenches 191 and second trenches 192 disposed between the plurality of sub-pixels SP1, SP2, and SP3 and extending in the second direction (the Y-axis direction). The plurality of sub-pixels SP1, SP2, and SP3 may be formed in quadrangular shapes, but the shapes of the sub-pixels are not necessarily limited thereto.

The plurality of sub-pixels SP1, SP2, and SP3 may be disposed on a plurality of pixel lines PL1, PL2, and PL3 disposed in the first direction (the X-axis direction). The plurality of pixel lines may be disposed to be spaced apart from each other in the second direction (the Y-axis direction).

For example, a first sub-pixel SP1, a second sub-pixel SP2, and a third sub-pixel SP3 may be sequentially disposed on a first pixel line PL1 in the first direction (the X-axis direction). Further, the first sub-pixel SP1, the second sub-pixel SP2, and the third sub-pixel SP3 may be sequentially disposed on a second pixel line PL2 in the first direction (the X-axis direction).

The first sub-pixel SP1, the second sub-pixel SP2, and the third sub-pixel SP3 may be sub-pixels of different colors. For example, the first sub-pixel SP1 may be a red sub-pixel, the second sub-pixel SP2 may be a green sub-pixel, and the third sub-pixel SP3 may be a blue sub-pixel. However, the present disclosure is not necessarily limited thereto, and a color of each sub-pixel may be changed in various ways.

The plurality of sub-pixels SP1, SP2, and SP3 disposed on the first pixel line PL1 and the plurality of sub-pixels SP1, SP2, and SP3 disposed on the second pixel line PL2 may be disposed to be misaligned from each other. Accordingly, the plurality of sub-pixels SP1, SP2, and SP3 may be disposed in a zigzag shape in the second direction (the Y-axis direction).

The plurality of sub-pixels SP1, SP2, and SP3 may have sub-pixels of different colors disposed in the first direction (the X-axis direction), the second direction (the Y-axis direction), and diagonal directions (E1 and E2 directions). The diagonal directions (the E1 and E2 directions) may be directions intersecting the first direction (the X-axis direction) and the second direction (the Y-axis direction) and in which the plurality of sub-pixels SP1, SP2, and SP3 are sequentially disposed. The plurality of sub-pixels SP1, SP2, and SP3 may have sub-pixels of different colors sequentially disposed in the first direction (the X-axis direction), and sub-pixels of different colors sequentially disposed in the diagonal directions (the E1 and E2 directions).

The first trenches 191 and the second trenches 192 may be disposed between the plurality of sub-pixels SP1, SP2, and SP3. The first trenches 191 and the second trenches 192 may extend in the second direction (the Y-axis direction) and the first direction (the X-axis direction) while being spaced apart from each other. In this case, the first trenches 191 and the second trenches 192 may be spaced apart from each other at a predetermined interval while extending in the second direction (the Y-axis direction) and thus may not meet each other.

A first spacing region SA1 having a first interval and a second spacing region SA2 having a second interval larger than the first interval may be repeatedly formed on the substrate 110 by the first trench 191 and the second trench 192. A plurality of first spacing regions SA1 and a plurality of second spacing regions SA2 may be alternately disposed in the second direction (the Y-axis direction). The sub-pixels may be respectively disposed in the plurality of second spacing regions SA2. Accordingly, since a light-emitting layer 140 of each sub-pixel is separated from a light-emitting layer 140 of the neighboring sub-pixel, a leakage current may be blocked.

The first trench 191 and the second trench 192 may be bent in directions away from each other along side surfaces of the sub-pixels while extending from the first pixel line PL1 to the second pixel line PL2. When the sub-pixel has a quadrangular shape, the first trench 191 and the second trench 192 may be bent in directions away from each other in the second direction (the Y-axis direction) between the first pixel line PL1 and the second pixel line PL2, and then may extend in the second direction (the Y-axis direction). The first trench 191 and the second trench 192 may be bent in directions approaching each other to be disposed between neighboring sub-pixels when extending to a third pixel line PL3 which is a next line.

Accordingly, both the first trenches 191 and the second trenches 192 are disposed between the plurality of sub-pixels SP1, SP2, and SP3 disposed in the first direction (the X-axis direction), but only one of the first trench 191 and the second trench 192 may be disposed between the plurality of sub-pixels SP1, SP2, and SP3 disposed in the diagonal directions (the E1 and E2 directions).

According to the embodiment, the plurality of first trenches 191 and the second trenches 192 may extend in the second direction (the Y-axis direction) and alternately form the plurality of first spacing regions SAI and second spacing regions SA2, and the plurality of sub-pixels SP1, SP2, and SP3 may be disposed in each second spacing region SA2. Accordingly, the plurality of sub-pixels SP1, SP2, and SP3 may be separated from the light-emitting layers 140 of adjacent sub-pixels in the first direction (the X-axis direction) and the diagonal directions (the E1 and E2 directions) to prevent a leakage current.

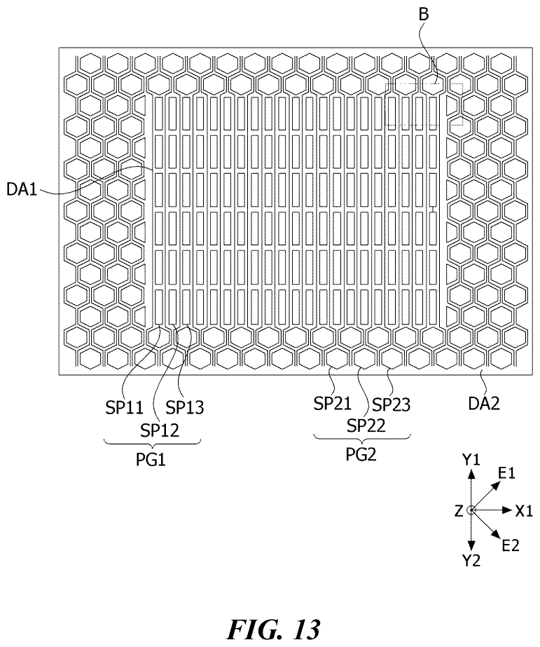

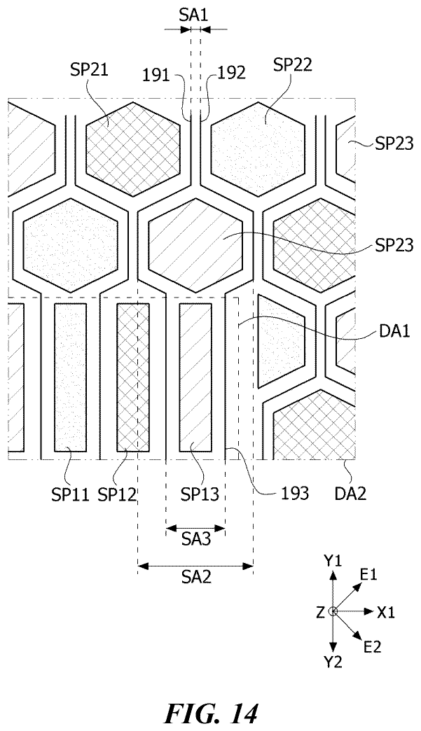

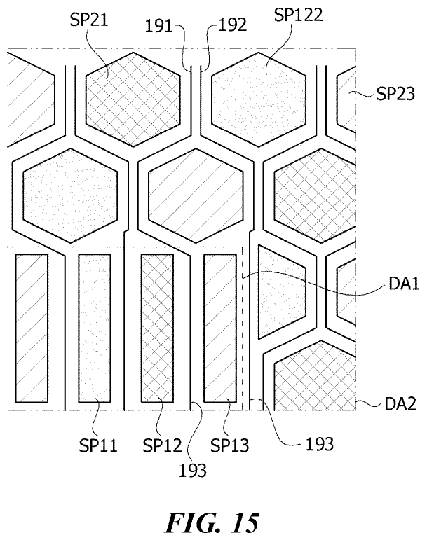

FIG. 13 is a view illustrating sub-pixels of a display device according to still another embodiment of the present disclosure. FIG. 14 is an enlarged view of portion B in FIG. 13. FIG. 15 is a modified example of FIG. 14.

Referring to FIGS. 13 and 14, the display device may include a first pixel group PG1 disposed in a first display region DA1 and a second pixel group PG2 disposed in a second display region DA2 surrounding the first display region DA1.

The first display region DA1 may be disposed in a central region, and the first pixel group PG1 disposed in the first display region DA1 may include a plurality of strip-shaped sub-pixels SP11, SP12, and SP13. The second display region DA2 may be an edge region surrounding the first display region DA1, and the second pixel group PG2 disposed in the second display region DA2 may include a plurality of polygonal-shaped sub-pixels SP21, SP22, and SP23. The sub-pixels SP21, SP22, and SP23 of the second pixel group PG2 may be disposed in a delta pixel structure.

The first display region DA1 may correspond to a focus region in the personal immersive device and may be a region where an image is displayed at a first resolution. The second display region DA2 may be an outer peripheral region and may be a region where an image is displayed at a second resolution lower than the first resolution. Accordingly, a size of the plurality of sub-pixels SP21, SP22, and SP23 disposed in the second display region DA2 may be larger than a size of the plurality of sub-pixels SP11, SP12, and SP13 disposed in the first display region DA1.

A plurality of third trenches 193 extending in the second direction (the Y-axis direction) may be disposed between the sub-pixels SP11, SP12, and SP13 of the first pixel group PG1. A plurality of first trenches 191 and second trenches 192 extending in the second direction (the Y-axis direction) may be disposed between the sub-pixels SP21, SP22, and SP23 of the second pixel group PG2. The plurality of third trenches 193 may be connected to one of the first trenches 191 and the second trenches 192.

The plurality of third trenches 193 may be connected to the plurality of first trenches 191 and second trenches 192. According to this configuration, a leakage current of the sub-pixels SP11, SP12, and SP13 in the first display region DA1 may be blocked by the third trenches 193, and a leakage current of the sub-pixels SP21, SP22, and SP23 in the second display region DA2 may be blocked by the first and second trenches 191 and 192.

First spacing regions SA1 where the first trenches 191 and the second trenches 192 are spaced apart from each other at a first interval and second spacing regions SA2 where the first trenches 191 and the second trenches 192 are spaced apart from each other at a second interval larger than the first interval may be disposed, and third spacing regions SA3 where the plurality of third trenches 193 are spaced apart from each other at a third interval may be disposed. The third spacing region SA3 may be wider than the first spacing region SA1 and narrower than the second spacing region SA2.

In this case, at a boundary between the first display region DA1 and the second display region DA2, the sub-pixels SP11, SP12, and SP13 of the first display region DA1 and the sub-pixels SP21, SP22, and SP23 of the second display region DA2 may be disposed to face each other with the same color. For example, the third sub-pixel SP23 of the second display region DA2 may be disposed adjacent to the third sub-pixel SP13 of the first display region DA1 disposed on the far right in FIG. 14.

According to this configuration, even when there is no trench between the third sub-pixel SP13 of the first display region DA1 and the third sub-pixel SP23 of the second display region DA2 in the second direction (the Y-axis direction), the third sub-pixel SP13 and the third sub-pixel SP23 have the same color, and thus colors mixing may be prevented.

Referring to FIG. 15, connection shapes of the first to third trenches 191, 192, and 193 may be modified in various ways depending on sizes and shapes of the sub-pixels of the first display region DA1 and the sub-pixels of the second display regions DA2. Further, the third trenches 193 of the first display region DA1 and the first and second trenches 191 and 192 of the second display region DA2 may be disposed in a disconnected state without being connected.

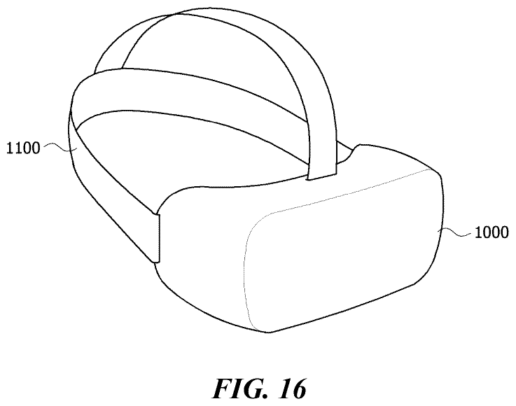

FIG. 16 is a view illustrating an example of a personal immersive device of a head mounted display (HMD) type. An exterior of the personal immersive device is not limited to the example of FIG. 16.

Referring to FIG. 16, the HMD type personal immersive device includes a main body 1000 and a head mounted band 1100.

The main body 1000 may include the display panel of the above-described embodiment, a lens disposed opposite to a screen of the display panel, a display panel driver, a system controller, a plurality of sensors, and the like. The main body 1000 may further include a camera. The lens may include an eyepiece lens or a fisheye lens. The display panel driver receives pixel data of an input image and drives the pixels to display the input image on the pixels of the display panel.

The system controller may include an external device interface connected to the sensors, the camera, and the like and also connected to a memory or an external video source, a user interface which receives user's commands, and one or more processors connected to a power supply unit which generates power. The sensors include various sensors such as a gyro sensor an acceleration sensor, and the like. The sensors transmit output of various sensors to the system controller. The system controller may receive the output of the sensors to execute a foveated rendering algorithm of moving the pixel data of the image displayed in the pixels of the display panel in synchronization with user's movement and following user's eyes.

A personal immersive device may be implemented using a mobile terminal system such as a smartphone. In this case, an image for a left eye and an image for a right eye may be displayed together on a display panel of the mobile terminal system. In the case of smartphones, a virtual reality (VR) mode is supported as an example of partial mode. In the VR mode of the smartphone, the image for the left eye and the image for the right eye may be separated and displayed together on one display panel. In this case, configurations of the main body 1000 in FIG. 16 may be simplified, and the mobile terminal system which supports the VR mode may be detachably mounted on the main body 1000.

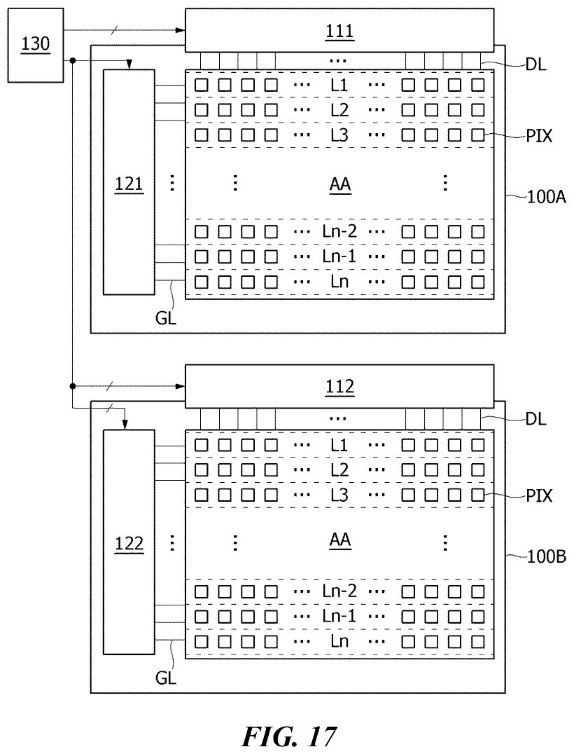

FIG. 17 is a block diagram illustrating an example of a display device applicable to the personal immersive device.

Referring to FIG. 17, the display device may include a first display panel 100A on which a left-eye image is displayed, and a second display panel 100B on which a right-eye image is displayed.

The display panels 100A and 100B include data lines DL, gate lines GL, and pixels PIX. Screens of the display panels 100A and 100B include pixel arrays on which images are displayed. The pixel array includes pixel lines L1 to Ln sequentially scanned by a scan pulse shifted in a scanning direction so that pixel data is written.

A display panel driver may include data drivers 111 and 112, gate drivers 121 and 122, a controller 130, and the like. The data drivers 111 and 112 and the gate drivers 121 and 122 may be separated for each of display panels 100A and 100B, and the controller 130 may be shared. The data drivers 111 and 112 convert pixel data input from the controller 130 to a voltage or current and supply data signals to pixels. The gate drivers 121 and 122 sequentially output scan pulses synchronized with the data signals output from the data drivers 111 and 112 under control of the controller 130.

According to one embodiment of the present disclosure, a problem of image quality deterioration can be resolved by blocking a leakage current occurring between sub-pixels. Accordingly, low-power driving is possible.

The effects according to the present specification are not limited to the above-mentioned effects, and other effects which are not mentioned can be clearly understood by those skilled in the art from the disclosure to be described below.

Since the content of the specification disclosed in the technical problems to be solved, technical solutions, and the effects described above do not specify essential features of the claims, the scope of the claims is not limited by the items disclosed in the content of the specification.

Although the embodiments of the present disclosure have been described in more detail with reference to the accompanying drawings, the present disclosure is not necessarily limited to these embodiments, and may be modified in various ways without departing from the technical spirit of the present disclosure. Accordingly, the embodiments disclosed in the present disclosure are not intended to limit the technical spirit of the present disclosure, but to describe the technical spirit of the present disclosure, and the scope of the technical spirit of the present disclosure is not limited by these embodiments. Accordingly, the above-described embodiments should be understood in all respects as illustrative and not restrictive.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate;
a plurality of sub-pixels disposed on the substrate in a first direction and a second direction, the first direction and the second direction intersecting each other; and
a first trench and a second trench in the substrate, the first trench and the second trench disposed between the plurality of sub-pixels and extending in the second direction,
wherein the first trench and the second trench are spaced apart from each other at a first interval in a first region of the substrate, and
wherein the first trench and the second trench are spaced apart from each other at a second interval greater than the first interval in a second region of the substrate, and
each of the plurality of sub-pixels is disposed in the second region.

2. The display device of claim 1, wherein the plurality of sub-pixels have different colors in the first direction and a diagonal direction intersecting the first direction and the second direction.

3. The display device of claim 2, wherein the plurality of sub-pixels are disposed in a zigzag shape in the second direction.

4. The display device of claim 2, wherein the plurality of sub-pixels include a first sub-pixel, a second sub-pixel, and a third sub-pixel with different colors, and
the first sub-pixel is surrounded by the second sub-pixel and the third sub-pixel, and
centers of the first sub-pixel, the second sub-pixel, and the third sub-pixel are disposed in a triangular shape.

5. The display device of claim 1, wherein each of the plurality of sub-pixels has a polygonal shape, an elliptical shape or a circular shape.

6. The display device of claim 1, wherein the plurality of sub-pixels include:
a plurality of first sub-pixels disposed on a first pixel line; and
a plurality of second sub-pixels disposed on a second pixel line spaced apart from the first pixel line, and
the plurality of first sub-pixels disposed on the first pixel line are disposed to be misaligned from the plurality of second sub-pixels disposed on the second pixel line in the second direction.

7. The display device of claim 6, wherein the first trench and the second trench are spaced apart from each other at the first interval on the first pixel line, and are configured to be bent away from each other and spaced apart from each other at the second interval on the second pixel line.

8. The display device of claim 1, wherein the plurality of sub-pixels include:
a plurality of first electrodes disposed in the plurality of sub-pixels;
a light-emitting layer disposed on the plurality of first electrodes; and
a second electrode disposed on the light-emitting layer,
the plurality of sub-pixels partitioned by the first trench and the second trench, and
portions of the light-emitting layer isolated by the first trench and the second trench.

9. The display device of claim 8, wherein the light-emitting layer includes a first stack, a charge generation layer disposed on the first stack, and a second stack disposed on the charge generation layer, and
the first stack and the charge generation layer are isolated by the first trench and the second trench, and at least a portion of the second stack is continuous.

10. The display device of claim 1, wherein the first trench and the second trench do not intersect in the second direction.

11. The display device of claim 1, wherein the first trench and the second trench each include first portions extending in a direction parallel to the second direction, second portions extending in a direction intersecting the second direction, and bent regions where the first portions and the second portions are connected, and
wherein the substrate is configured to bend at the bent regions.

12. The display device of claim 1, wherein the second direction is perpendicular to the first direction.

13. The display device of claim 1, wherein the display device comprises a first pixel group disposed in a first display region and a second pixel group disposed in a second display region surrounding the first display region, a size of the plurality of sub-pixels disposed in the second display region is larger than a size of the plurality of sub-pixels disposed in the first display region,
wherein a plurality of third trenches extending in the second direction are disposed between the sub-pixels of the first pixel group, and the first trench and the second trench are disposed between the sub-pixels of the second pixel group, and
wherein the display device further comprises the plurality of third trenches being spaced apart from each other at a third interval in a third region of the substrate, and the third region is wider than the first region and narrower than the second region.

14. The display device of claim 13, wherein the sub-pixels of the first display region and the sub-pixels of the second display region face each other and have the same color at a boundary between the first display region and the second display region.

15. The display device of claim 13, wherein the plurality of third trenches are connected to the first trench and the second trench.

16. The display device of claim 13, wherein the third trenches are isolated from the first trench and the second trench.

17. A display device comprising:
a substrate;
a plurality of sub-pixels disposed on the substrate in a first direction and a second direction, the second direction perpendicular to the first direction; and
trenches disposed between the plurality of sub-pixels,
wherein a number of trenches disposed between the plurality of sub-pixels in the first direction is greater than or equal to a number of trenches disposed between the sub-pixels in a diagonal direction.

18. The display device of claim 17, wherein the plurality of sub-pixels have different colors in the first direction and in the diagonal direction, and
the diagonal direction is a direction intersecting the first direction and the second direction.

19. The display device of claim 17, wherein the trenches disposed between the sub-pixels in the first direction are connected to the trenches disposed between the sub-pixels in the diagonal direction.

20. The display device of claim 17, wherein two first grooves are disposed between the sub-pixels disposed in the first direction, and
one second groove is disposed between the sub-pixels disposed in the diagonal direction.
